(19) United States
(12) Patent Application Publication
(10) Pub. No.: US 2025/0183616 A1
(43) Pub. Date: Jun. 5, 2025

(54) INTEGRATED LASER MODULATOR WITH E-STOPPER LAYER

(71) Applicant: Lumentum Technology (UK) Limited, Northamptonshire (GB)

(72) Inventors: Andrew John WARD, Caswell (GB); Simeon KAUNGA-NYIRENDA, Nottingham (GB); Md Nazmul HOSSAIN, Northampton (GB); Keith GRIFFITHS, Brackley (GB)

(21) Appl. No.: 18/425,706

(22) Filed: Jan. 29, 2024

Related U.S. Application Data
(60) Provisional application No. 63/605,222, filed on Dec. 1, 2023.

(51) Int. Cl. H01S 5/026; G02B 6/12; H01S 5/343

(52) U.S. Cl. CPC H01S 5/0265; G02B 6/12004; H01S 5/34306; G02B 2006/12121

(57) ABSTRACT

An integrated laser modulator includes a substrate, a laser active region disposed on the substrate, a modulator region disposed on the substrate, and an e-stopper layer disposed on at least the laser active region. The substrate and the laser active region are associated with an indium gallium arsenide phosphide (InGaAsP) material system. The modulator region is associated with InGaAsP material system or an aluminum indium gallium arsenide (AlInGaAs) material system. The e-stopper layer comprises aluminum indium arsenide (AlInAs). The e-stopper layer is disposed greater than 100 nanometers away from a quantum element of the laser active region. The modulator region includes an end surface that interfaces with an end surface of the laser active region.

### CROSS-REFERENCE TO RELATED APPLICATION

This patent application claims priority to U.S. Patent Application No. 63/605,222, filed on Dec. 1, 2023, and entitled “E-STOPPER LAYER IN LASER STRUCTURE.” The disclosure of the prior application is considered part of and is incorporated by reference into this patent application.

### TECHNICAL FIELD

The present disclosure relates generally to an integrated laser modulator and to an integrated laser modulator with an electron stopper (“e-stopper”) layer.

### BACKGROUND

A laser can be associated with an aluminum indium gallium arsenide (AlInGaAs) material system (e.g., where aluminum indium gallium arsenide (AlInAs) is a part of the material system) and can include a laser active region (e.g., that includes one or more quantum wells (QWs)). One side of the laser active region is associated with a p-side of the laser (e.g., that includes p-doped layers and/or structures) and an opposite side of the laser active region is associated with an n-side of the laser (e.g., that includes n-doped layers and/or structures). In some cases, a layer of AlInAs may be disposed within the laser active region (e.g., in a position closer to the p-side of the laser than the n-side of the laser). The AlInAs layer can provide a barrier to electrons passing from the n-side of the laser to the p-side of the laser and therefore can be referred to as an e-stopper layer.

### SUMMARY

In some implementations, an integrated laser modulator includes a substrate; a laser active region disposed on the substrate; a modulator region disposed on the substrate; and an e-stopper layer disposed on at least the laser active region, wherein: the substrate and the laser active region are associated with an indium gallium arsenide phosphide (InGaAsP) material system, the modulator region is associated with InGaAsP material system or an aluminum indium gallium arsenide (AlInGaAs) material system, the e-stopper layer comprises aluminum indium arsenide (AlInAs), the e-stopper layer is disposed greater than 100 nanometers away from a quantum element of the laser active region, and the modulator region includes an end surface that interfaces with an end surface of the laser active region.

In some implementations, a photonic integrated circuit (PIC) includes a laser active region disposed on a substrate; a modulator region disposed on the substrate; and an e-stopper layer disposed on at least the laser active region, wherein: the laser active region is associated with an InGaAsP material system, the e-stopper layer comprises AlInAs, and the e-stopper layer is disposed on a separate confinement heterostructure (SCH) layer of the laser active region.

In some implementations, an optical device includes an integrated laser modulator that includes: a laser active region; a modulator region; and an e-stopper layer disposed on at least the laser active region, wherein: the laser active region is associated with an InGaAsP material system, the e-stopper layer comprises AlInAs, and the e-stopper layer is disposed greater than 100 nanometers away from a quantum element of the laser active region.

### BRIEF DESCRIPTION OF THE DRAWINGS

FIGS. 1A-1C are diagrams associated with an example optical device.

FIGS. 2A-2B show example plots related to an effect of an e-stopper layer.

### DETAILED DESCRIPTION

The following detailed description of example implementations refers to the accompanying drawings. The same reference numbers in different drawings may identify the same or similar elements.

In many cases, semiconductor edge-emitting diode lasers can suffer from high vertical leakage currents, particularly at high temperatures where electrons can possess a lot of thermal energy. An e-stopper layer that comprises AlInAs can be included in a laser active region of a laser associated with an AlInGaAs material system (e.g., as described above) to reduce vertical leakage current within the laser, which can therefore improve efficiency of the laser. For example, the e-stopper layer can impede electrons, that flow from an n-side of the laser to a p-side of the laser (via the laser active region), from flowing all the way to a p-contact on a p-side of the laser (e.g., that is beyond the laser active region). Accordingly, the e-stopper layer facilitates confinement of electrons within the laser active region, which improves a likelihood that electrons radiatively combine with holes within the laser active region and thereby produce light.

Lasers built using an indium gallium arsenide phosphide (InGaAsP) material system also suffer from vertical leakage currents. However, an e-stopper layer associated with an InGaAsP material system does not exist because bandgaps and conduction band offsets in the InGaAsP material system inhibit creating a barrier that effectively blocks electrons from flowing through a laser and combining with holes to produce light (e.g., via radiative recombination).

Further, in many cases, an e-stopper layer that comprises AlInAs is not practically available in a photonic integrated circuit (PIC), such as a PIC that includes an integrated laser modulator, that is associated with an InGaAsP material system. This is because aluminum typically oxidizes upon being exposed to air, which creates defects within the PIC. For example, during an etch and regrowth process for forming a laser region and an optical modulator region within the PIC, oxidation of the aluminum in an AlInGaAs e-stopper layer of a laser active region of the laser region of the PIC results in a high defect density at an interface between the laser region and the optical modulator region (commonly referred to as a “butt-join”). The high defect density at the interface reduces a reliability of the PIC. Further, when the laser is associated with the InGaAsP material system and configured to operate at a short spectral range (e.g., a spectral range from 1250 to 1360 nm), the PIC is subject to a higher photon energy (e.g., as compared to a laser configured to operate at a longer spectral range, such as one centered at 1550 nm), which can cause any existing defects at the interface between the laser region and the optical modulator region to increase in size and/or severity. This further reduces the reliability of the PIC.

Consequently, there is a need to incorporate an e-stopper layer into a PIC (e.g., that includes an integrated laser modulator) that is associated with the InGaAsP material system that can improve an efficiency of a light producing portion (e.g., a laser) of the PIC (e.g., by blocking electrons from flowing through the laser section and thereby causing the electrons to combine with holes to produce light), while ensuring a reliability of the PIC (e.g., by minimizing a defect density at an interface between the laser and an optical modulator of the PIC).

Some implementations described herein include a PIC that includes an integrated laser modulator. The PIC includes a substrate, a laser active region disposed on the substrate, a modulator region disposed on the substrate, and an e-stopper layer disposed on at least the laser active region. The substrate and the laser active region are associated with the InGaAsP material system. The modulator region is associated with InGaAsP material system or the AlInGaAs material system. The modulator region includes an end surface that interfaces with an end surface of the laser active region.

The e-stopper layer comprises aluminum indium arsenide (AlInAs). The e-stopper layer is configured to reduce leakage current (e.g., vertical leakage current) within the PIC (e.g., within the laser active region of the PIC). Accordingly, the e-stopper layer improves an efficiency of the PIC (e.g., an efficiency of the laser active region). For example, the e-stopper layer (when positioned on a p-side of the PIC) may be configured to impede electrons, that flow from an n-side of the PIC to the p-side of the PIC, from flowing past the e-stopper layer. Accordingly, the e-stopper layer is configured to facilitate confinement of electrons within the laser active region (e.g., because the e-stopper layer is disposed on the laser active region such that a distance between the e-stopper layer and the laser active region is optimized to ensure that at least a portion of electrons that are “stopped” by the e-stopper layer are redirected back to the laser active region), which improves a likelihood that the portion of electrons combine with holes within the laser active region and thereby produce light.

In some implementations, the e-stopper layer may be disposed greater than a threshold distance away from a quantum element (e.g., a quantum well or a quantum dot layer) of the laser active region, which minimizes a likelihood of defects associated with oxidation of the e-stopper layer propagating to the quantum element and thereby affecting a light production performance of the laser active region. For example, the laser active region may include a separate confinement heterostructure (SCH) layer (e.g., that is hundreds of nanometers thick) disposed on (e.g., above) the quantum element, and the e-stopper layer may be disposed on (e.g., above) the SCH layer. Further, the PIC may include one or more encapsulating layers that are configured to encapsulate the e-stopper layer and therefore to prevent, or at least minimize, oxidation of the e-stopper layer. In this way, oxidation defects within the PIC are minimized, which improves a reliability of the PIC. Further, because the e-stopper layer is disposed on the laser active region, and not within the laser active region, oxidation defects associated with the e-stopper layer are unlikely to be present at any interface between the laser active region and the modulator region. This further improves a reliability of the PIC.

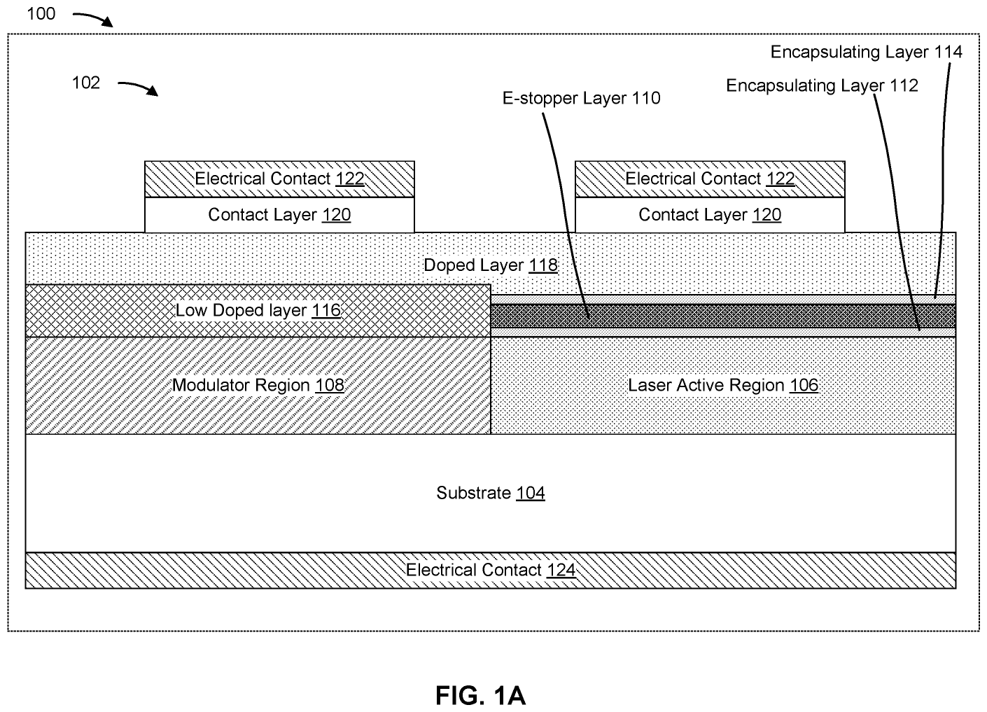

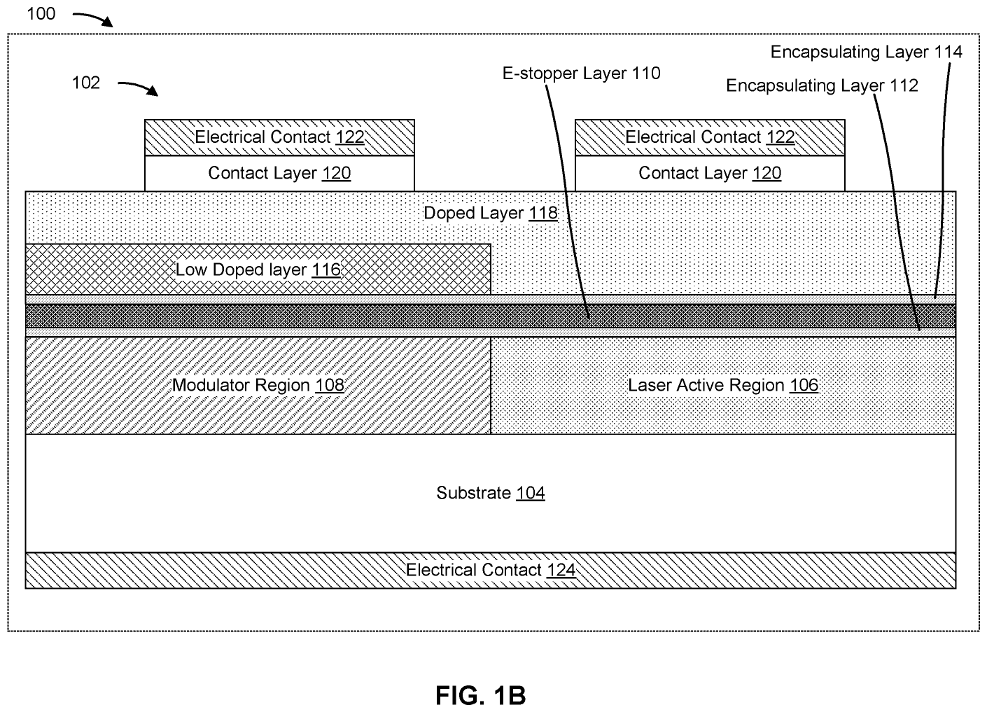

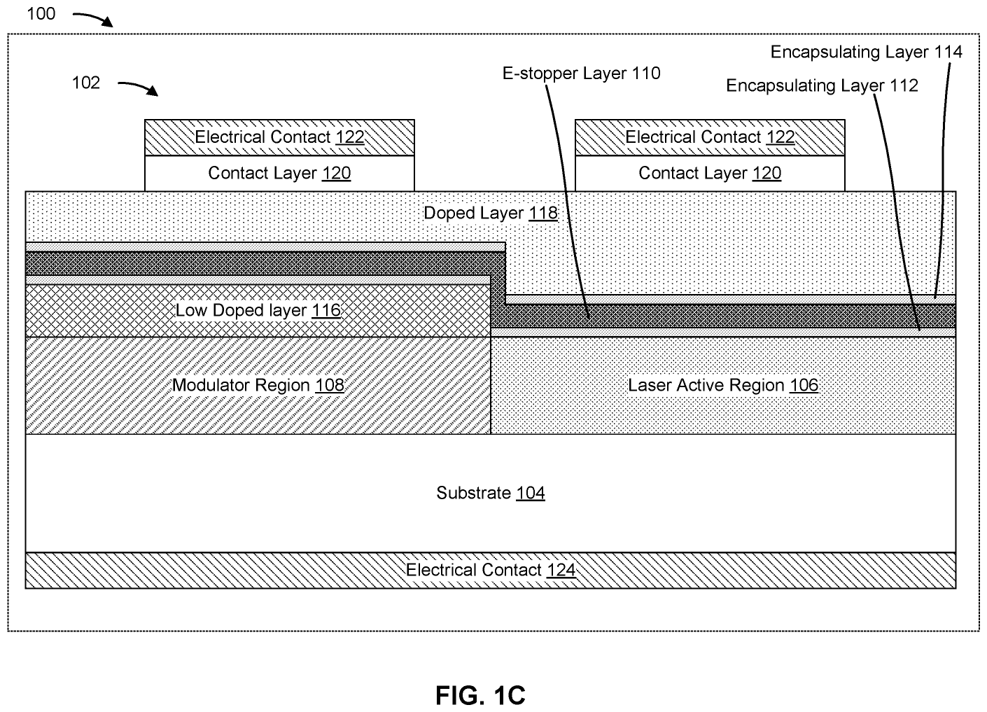

FIGS. 1A-1C are diagrams associated with an example optical device 100. The optical device 100 may include, for example, an optical communication device, an optical sensing device, an optical interconnection device, an optical structured light device, or another type of optical device.

As shown in FIGS. 1A-1C, the optical device 100 may include a photonic integrated circuit (PIC) 102, which may integrate multiple photonic components on a single chip (e.g., a single substrate). For example, the PIC 102 may include an integrated laser modulator (e.g., that integrates a laser and an optical modulator), which may be configured to operate at a spectral range from 1250 to 1360 nanometers (nm) (e.g., greater than or equal to 1250 nm and less than or equal to 1360 nm). The spectral range may be, for example, centered at 1300 nm (or another wavelength within the spectral range). In some implementations, the spectral range may be from 1250 to 1625 nm, and may be centered at a particular wavelength within the spectral range depending on an application of the optical device 100.

Accordingly, as shown in FIGS. 1A-1C, the PIC 102 may include a substrate 104, a laser active region 106 (e.g., disposed on the substrate 104), a modulator region 108 (e.g., disposed on the substrate 104), and/or an e-stopper layer 110 (e.g., disposed on at least the laser active region 106). FIG. 1A shows a configuration where the e-stopper layer 110 is disposed on only the laser active region 106, and FIGS. 1B-1C show configurations where the e-stopper layer 110 is disposed on the laser active region 106 and on the modulator region 108. As further shown in FIGS. 1A-1C, the PIC 102 may also include a first encapsulating layer 112, a second encapsulating layer 114, a low doped layer 116, a doped layer 118, a one or more contact layers 120, one or more electrical contacts 122, and/or an electrical contact 124.

The substrate 104 includes a supporting material upon which, or within which, one or more layers or features of the PIC 102 are grown or fabricated. In some implementations, the substrate 104 may be associated with an indium gallium arsenide phosphide (InGaAsP) material system. For example, the substrate 104 may include indium phosphide (InP) or another type of material from the InGaAsP material system.

In some implementations, the substrate 104 may be doped. For example, the substrate 104 may be doped with an n-type dopant (and therefore the substrate 104 may be referred to as an n-type substrate) or a p-type dopant (and therefore the substrate 104 may be referred to as an p-type substrate). In a specific n-doped example, the substrate 104 may comprise n-doped InP or another n-doped material from the InGaAsP material system. In some implementations, the substrate 104 may be doped with a flat doping profile, a graded doping profile, or another type of doping profile.

In some implementations, the substrate 104 may be a semi-insulating substrate (e.g., achieved by doping the substrate 104 with iron (Fe) or another material). For example, the substrate 104 may comprise semi-insulating InP or another semi-insulating material from the InGaAsP material system.

The laser active region 106 may be disposed on the substrate 104 (e.g., on a region of a top surface of the substrate 104, such as a right region of the top surface of the substrate 104, as shown in FIGS. 1A-1C). The laser active region 106 may be configured to generate and amplify light (e.g., coherent light, such as a laser beam). For example, the laser active region 106 may include one or more layers where electrons and holes recombine to generate and emit light and define an emission wavelength range of the PIC 102. In some implementations, the laser active region 106 may include one or more quantum wells and/or one or more quantum dot layers. Additionally, the laser active region 106 may include an SCH layer disposed on (e.g., above) the one or more quantum wells (e.g., to confine carriers within the laser active region), such that the SCH layer may be closer to a top surface of the laser active region 106 than any of the one or more quantum wells.

In some implementations, the laser active region 106 may be associated with the InGaAsP material system. For example, the laser active region 106 may include InGaAsP, InP, or another type of material from the InGaAsP material system. In some implementations, the laser active region 106 may be at least partially undoped (e.g., not intentionally doped). For example, the laser active region 106 may include at least one layer with undoped InGaAsP, undoped InP, or another type of undoped material from the InGaAsP material system. Additionally, or alternatively, the laser active region 106 may be at least partially doped. For example, the laser active region 106 may include at least one layer doped with an n-type dopant or a p-type dopant. In a specific n-doped example, the laser active region 106 may comprise n-doped InGaAsP, n-doped InP, or another type of n-doped material from the InGaAsP material system. In some implementations, a doped layer of the laser active region 106 may be doped with a flat doping profile, a graded doping profile, or another type of doping profile.

The modulator region 108 may be disposed on the substrate 104 (e.g., on a region of the top surface of the substrate 104, such as a left region of the top surface of the substrate 104, as shown in FIGS. 1A-1C). The modulator region 108 may be configured to modulate the light generated and emitted by the laser active region 106. For example, an electrical voltage may be applied across the modulator region 108 (e.g., via the substrate 104 and/or the low doped layer 116) to cause a refractive index of the modulator region 108 to change (e.g., based on an electro-optic effect), which thereby enables modulation of the light generated and emitted by the laser active region 106. In some implementations, the modulator region 108 may include one or more Mach-Zehnder interferometers (MZIs), one or more electro-absorption modulators (EAMs), and/or similar structures to modulate light.

In some implementations, the modulator region 108 may be associated with the InGaAsP material system. For example, the modulator region 108 may include InGaAsP, InP, or another type of material from the InGaAsP material system. Alternatively, the modulator region 108 may be associated with the AlInGaAs material system. For example, the modulator region 108 may include AlInGaAs, AlInAs, or another type of material from the AlInGaAs material system.

In some implementations, the modulator region 108 may be at least partially undoped. For example, the modulator region 108 may include at least one layer with undoped InGaAsP, undoped InP, or another type of undoped material from the InGaAsP material system, or, alternatively, undoped AlInGaAs, undoped AlInAs, or another type of undoped material from the AlInGaAs material system. Additionally, or alternatively, the modulator region 108 may be at least partially doped. For example, the modulator region 108 may include at least one layer doped with an n-type dopant or a p-type dopant. In a specific n-doped example, the modulator region 108 may comprise n-doped InGaAsP, n-doped InP, or another type of n-doped material from the InGaAsP material system, or, alternatively, n-doped AlInGaAs, n-doped AlInAs, or another type of n-doped material from the AlInGaAs material system. In some implementations, a doped layer of the modulator region 108 may be doped with a flat doping profile, a graded doping profile, or another type of doping profile.

The modulator region 108 may include an end surface that interfaces with (e.g., directly contacts) an end surface of the laser active region 106. For example, as shown in FIGS. 1A-1C, a right end surface of the modulator region 108 interfaces with a left end surface of the laser active region 106. Such an interface is sometimes referred to as a “butt-join.” In some implementations, the laser active region 106 and the modulator region 108 may be formed such that defects (e.g., oxidation defects) at an interface between adjacent end surfaces of the laser active region 106 and the modulator region 108 are minimized.

The e-stopper layer 110 may be disposed on (e.g., above, or outside of) the laser active region 106 (e.g., may be disposed on a region of a top surface of the laser active region 106, such as shown in FIGS. 1A-1C) (e.g., when the laser active region 106 is formed on the substrate 104 using a first formation step, and the e-stopper layer 110 is formed on the laser active region 106 using a separate, second formation step). As shown in FIGS. 1B-1C, the e-stopper layer 110 may also be disposed on the modulator region 108 (e.g., when the laser active region 106 and the modulator region 108 are formed on the substrate 104 using a first formation step, and the e-stopper layer 110 is formed on the laser active region 106 using a separate, second formation step). The e-stopper layer 110 may be configured to reduce leakage current (e.g., vertical leakage current) within the PIC 102 (e.g., within the laser active region 106 of the PIC 102). Accordingly, the e-stopper layer 110 may improve an efficiency of the PIC 102 (e.g., an efficiency of the laser active region 106). For example, the e-stopper layer 110 may be configured to impede electrons, that flow from an n-side of the PIC 102 (e.g., from a side associated with the substrate 104) to a p-side of the PIC 102 (e.g., to a side associated with the doped layer 118, described herein), from flowing past the e-stopper layer 110 into the doped layer 118. Accordingly, the e-stopper layer 110 may be configured to facilitate confinement of electrons within the laser active region 106 (e.g., because the e-stopper layer 110 is disposed on the laser active region 106 such that a distance between the e-stopper layer 110 and the laser active region 106 is optimized to ensure that at least a portion of electrons that are “stopped” by the e-stopper layer 110 are redirected back to the laser active region 106), which improves a likelihood that the portion of electrons combine with holes within the laser active region 106 and thereby produce light.

In some implementations, the e-stopper layer 110 may be associated with the AlInGaAs material system. For example, the laser active region 106 may include AlInGaAs, AlInAs, or another type of material from the AlInGaAs material system. In some implementations, the e-stopper layer 110 may be undoped. For example, the e-stopper layer 110 may comprise undoped AlInGaAs, undoped AlInAs, or another type of undoped material from the AlInGaAs material system. Alternatively, the e-stopper layer 110 may be doped. For example, the e-stopper layer 110 may be doped with a p-type dopant. In a specific p-doped example, the e-stopper layer 110 may comprise p-doped AlInGaAs, p-doped AlInAs, or another type of p-doped material from the AlInGaAs material system. In some implementations, the e-stopper layer 110 may be doped with a flat doping profile, a graded doping profile, or another type of doping profile.

In some implementations, the e-stopper layer 110 may be disposed greater than a threshold distance away from a quantum element (e.g., a quantum well or a quantum dot layer) of the laser active region 106 (e.g., a quantum element of the laser active region 106 that is closest to the e-stopper layer 110 than other quantum elements of the laser active region 106). For example, when the laser active region 106 includes an SCH layer, the e-stopper layer 110 may be disposed on (e.g., above) the SCH layer, and thereby the e-stopper layer 110 may be disposed at least a distance away from the quantum element that is greater than or equal to a thickness of the SCH layer (e.g., that may be 100 nm, 200 nm, 300 nm, or more, thick). In this way, the e-stopper layer 110 may be a sufficient distance away from the quantum element of laser active region 106 such as to minimize a likelihood of defects associated with oxidation of the e-stopper layer 110 (e.g., when the e-stopper layer 110 comprises AlInGaAs, AlInAs, or another type of material from the AlInGaAs material system that is susceptible to oxidation) propagating to the quantum element and thereby affecting a light production performance of the laser active region 106. The threshold distance may be, for example, 100 nm, 150 nm, 200 nm, 250 nm, 300 nm, 350 nm, or another distance that reduces propagation of oxidation defects associated with the e-stoper layer 110 propagating to the quantum element of the laser active region 106. Accordingly, the e-stopper layer 110 is understood to be outside (e.g., not included in) the laser active region 106.

The e-stopper layer 110 may be associated with the first encapsulating layer 112 and/or the second encapsulating layer 114. The first encapsulating layer 112 may be disposed between the laser active region 106 and the e-stopper layer 110. For example, as shown in FIGS. 1A-1C, a bottom surface of the first encapsulating layer 112 may be disposed directly on a top surface of the laser active region 106, and a top surface of the first encapsulating layer 112 may be disposed directly on a bottom surface of the e-stopper layer 110. The second encapsulating layer 114 may be disposed between the e-stopper layer 110 and another layer (e.g., other than the laser active region 106), such as the doped layer 118. For example, as shown in FIGS. 1A-1C, a bottom surface of the second encapsulating layer 114 may be disposed directly on a top surface of the e-stopper layer 110, and a top surface of the second encapsulating layer 114 may be disposed directly on a bottom surface of the contact layer 120.

Each of the first encapsulating layer 112 and the second encapsulating layer 114 may be configured to encapsulate the e-stopper layer 110. For example, the first encapsulating layer 112 may be configured to encapsulate the bottom surface of the e-stopper layer 110, and the second encapsulating layer 114 may be configured to encapsulate the top surface of the e-stopper layer 110. That is, each of the first encapsulating layer 112 and the second encapsulating layer 114 may be configured to protect the e-stopper layer 110 from being exposed to air (e.g., during a formation phase for forming the e-stopper layer 110, which may be a separate formation phase than that for forming the laser active region 106 or another layer, such as the doped layer 118). In this way, each of the first encapsulating layer 112 and the second encapsulating layer 114 may be configured to prevent, or at least minimize, oxidation of the e-stopper layer 110 (e.g., when the e-stopper layer 110 comprises AlInGaAs, AlInAs, or another type of material from the AlInGaAs material system that is susceptible to oxidation). For example, the first encapsulating layer 112, when present, may cause the bottom surface of the e-stopper layer 110 to not be oxidized (or to be only minimally oxidized), and the second encapsulating layer 114, when present, may cause the top surface of the e-stopper layer 110 to not be oxidized (or to be only minimally oxidized).

In some implementations, each of the first encapsulating layer 112 and the second encapsulating layer 114 may be associated with the InGaAsP material system. For example, each of the first encapsulating layer 112 and the second encapsulating layer 114 may include InGaAsP, InP, or another type of material from the InGaAsP material system. In some implementations, at least one of the first encapsulating layer 112 or the second encapsulating layer 114 may be undoped. For example, at least one of the first encapsulating layer 112 or the second encapsulating layer 114 may comprise undoped InGaAsP, undoped InP, or another type of undoped material from the InGaAsP material system. Additionally, or alternatively, at least one of the first encapsulating layer 112 or the second encapsulating layer 114 may be doped. For example, at least one of the first encapsulating layer 112 or the second encapsulating layer 114 may be doped with a p-type dopant. In a specific p-doped example, each of the first encapsulating layer 112 and the second encapsulating layer 114 may comprise p-doped InGaAsP, p-doped InP, or another type of p-doped material from the InGaAsP material system. In some implementations, at least one of the first encapsulating layer 112 or the second encapsulating layer 114 may be doped with a flat doping profile, a graded doping profile, or another type of doping profile.

The low doped layer 116 may be disposed on the modulator region 108. For example, as shown in FIGS. 1A-1C, the low doped layer 116 may be directly disposed on the modulator region 108. As an alternative example, as shown in FIG. 1B, the low doped layer 116 may be indirectly disposed on the modulator region 108, such as via the e-stopper layer 110 (and the first encapsulating layer 112 and/or the second encapsulating layer 114). The low doped layer 116 may be configured to provide an optimal or appropriate waveguide design for the modulator region 108. In some implementations, the low doped layer 116 may be associated with the InGaAsP material system. For example, the low doped layer 116 may include InGaAsP, InP, or another type of material from the InGaAsP material system. In some implementations, each the low doped layer 116 may be doped with a p-type dopant (e.g., in a doping concentration that is less than that of the doped layer 118). In a specific p-doped example, the low doped layer 116 may comprise p-doped InGaAsP, p-doped InP, or another type of p-doped material from the InGaAsP material system. In some implementations, the low doped layer 116 may be doped with a flat doping profile, a graded doping profile, or another type of doping profile.

The doped layer 118 may be disposed on the e-stopper layer 110 (e.g., via the second encapsulating layer 114, when present) and/or the low doped layer 116. For example, as shown in FIGS. 1A-1C, the doped layer 118 may extend across a width of the PIC 102 such that it covers the e-stopper layer 110 and the low doped layer 116. In some implementations, the doped layer 118 may be associated with the InGaAsP material system. For example, doped layer 118 may include InP or another type of material from the InGaAsP material system. In some implementations, the doped layer 118 may be doped with a p-type dopant. In a specific p-doped example, the doped layer 118 may comprise p-doped InP or another type of p-doped material from the InGaAsP material system. In some implementations, the doped layer 118 may be doped with a flat doping profile, a graded doping profile, or another type of doping profile.

The one or more contact layers 120 may be disposed on the doped layer 118. For example, as shown in FIGS. 1A-1C, a left contact layer 120 may be disposed on a left region of the top surface of the doped layer 118 (e.g., such that the left contact layer 120 is vertically aligned with the modulator region 108) and a right contact layer 120 may be disposed on a right region of the top surface of the doped layer 118 (e.g., such that the right contact layer 120 is vertically aligned with the laser active region 106). Each contact layer 120 may be configured to allow electric current to flow to or from a corresponding electrical contact 122 of the one or more electrical contacts 122. In some implementations, each contact layer 120 may be associated with the InGaAsP material system. For example, each contact layer 120 may include indium gallium arsenide (InGaAs), InP, or another type of material from the InGaAsP material system. In some implementations, each contact layer 120 may be doped with a p-type dopant. In a specific p-doped example, each contact layer 120 may comprise p-doped InGaAs, p-doped InP, or another type of p-doped material from the InGaAsP material system. In some implementations, each contact layer 120 may be doped with a flat doping profile, a graded doping profile, or another type of doping profile.

Each electrical contact 122 may be disposed on a corresponding contact layer 120 of the one or more contact layers 120. For example, as shown in FIGS. 1A-1C, a left electrical contact 122 may be disposed on the left contact layer 120 (e.g., such that the left electrical contact 122 is vertically aligned with the modulator region 108) and a right electrical contact 122 is disposed on the right contact layer 120 (e.g., such that the right electrical contact 122 is vertically aligned with the laser active region 106). Each electrical contact 122 be configured to facilitate an electrical connection for the PIC 102 (e.g., by contacting a corresponding contact layer 120). For example, each electrical contact 122 may be configured to be an anode for the PIC 102, such as where the left electrical contact 122 is configured to be an anode associated with the modulator region 108 and/or the right electrical contact 122 is configured to be an anode associated with the laser active region 106. In some implementations, each electrical contact 122 may comprise a metal, such as gold (Au), and/or a metal alloy, such as gold-zinc (Au—Zn), among other examples, through which electrical current may flow.

The electrical contact 124 may be disposed on the substrate 104. For example, when the substrate 104 is a doped substrate (e.g., an n-doped substrate), the electrical contact 124 may be disposed on a bottom surface of the substrate 104, such as shown in FIGS. 1A-1C. The electrical contact 124 be configured to facilitate an electrical connection for the PIC 102 (e.g., by contacting the substrate 104). For example, the electrical contact 124 may be configured to be a cathode for the PIC 102, such as a cathode associated with the modulator region 108 and/or a cathode associated with the laser active region 106. In some implementations, the electrical contact 124 may comprise a metal, such as Au, and/or a metal alloy, such as Au—Zn, among other examples, through which electrical current may flow.

In some implementations, when the substrate 104 is a semi-insulating substrate, the electrical contact 124 may be disposed on the substrate via another contact layer (e.g., that is the same as, or similar to, the one or more contact layers 120), not shown. The other contact layer may be doped with an n-type dopant. In a specific n-doped example, the other contact layer may comprise n-doped InP or another type of n-doped material from the InGaAsP material system.

The number, arrangement, thicknesses, order, symmetry, or the like, of layers shown in FIGS. 1A-1C are provided as an example. In practice, the optical device 100 may include additional layers, fewer layers, different layers, differently constructed layers, or differently arranged layers than those shown in FIGS. 1A-1C. For example, the optical device 100 may in some implementations include layers that are doped differently (e.g., a layer described as n-doped may be p-doped, or vice versa) than described herein in relation to FIGS. 1A-1C. Additionally, or alternatively, a set of layers (e.g., one or more layers) of the optical device 100 may perform one or more functions described as being performed by another set of layers of the optical device 100, and any layer may include more than one layer. While some implementations described herein are directed to a single PIC (e.g., PIC 102), some implementations include multiple PICs (e.g., multiple PICs 102).

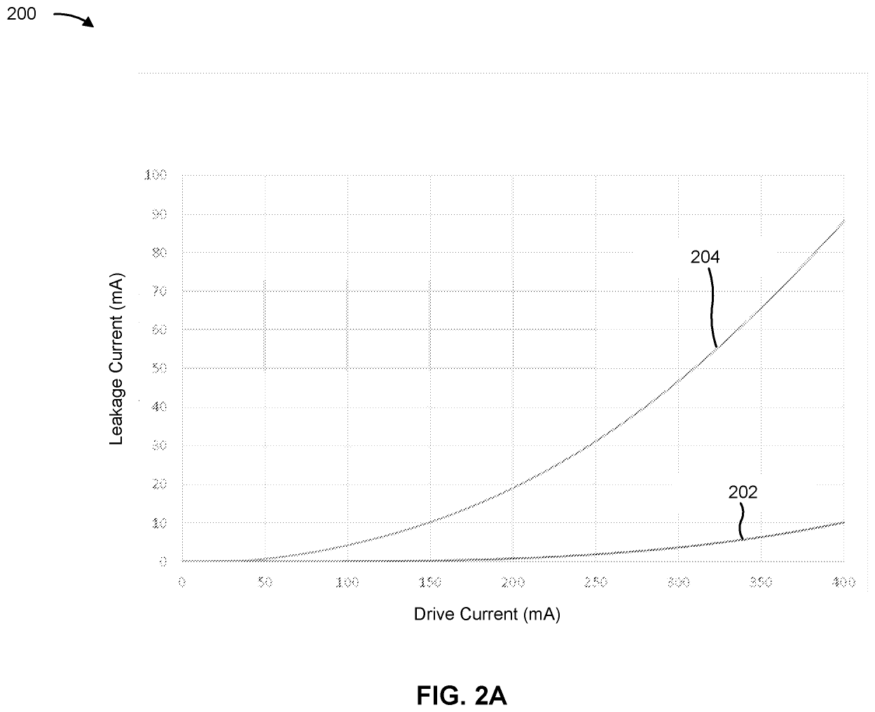

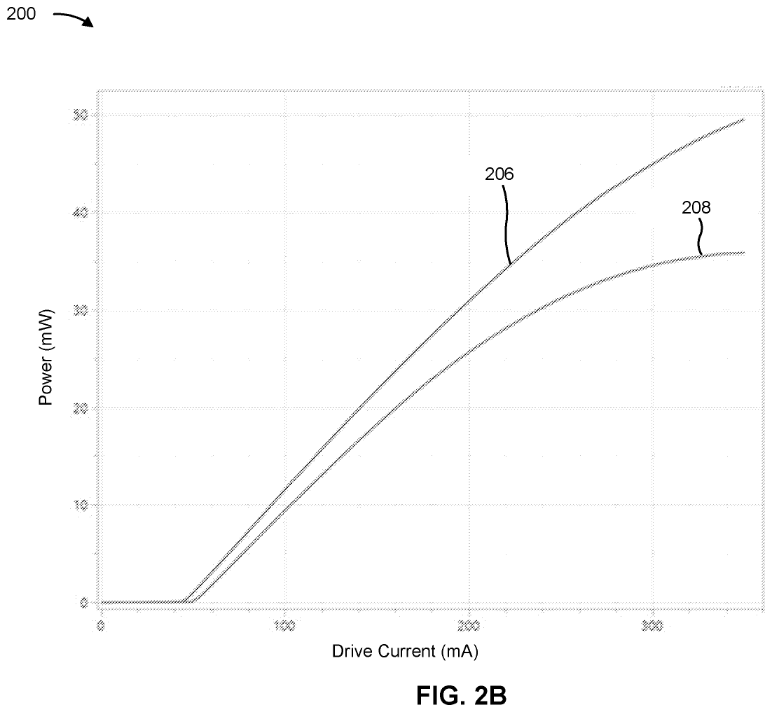

FIGS. 2A-2B show example plots 200 related to an effect of the e-stopper layer 110. FIG. 2A shows an effect of the e-stopper layer 110 on a leakage current of the PIC 102. As shown by curve 202 in FIG. 2A, a leakage current (e.g., a vertical leakage current, measured in milliamps (mA)) for the PIC 102 (e.g., that includes the e-stopper layer 110) described herein in relation to FIGS. 1A-1C may be lower, across a drive current from 0 to 400 mA, than a leakage current, shown by curve 204, for a similar, but differently structured PIC (e.g., a PIC that has a similar structure as the PIC 102, but does not include the e-stopper layer 110) across the drive current.

FIG. 2B shows an effect of the e-stopper layer 110 on an output power of the PIC 102. As shown by curve 206 in FIG. 2B, an output power (measured in mW) for the PIC 102 (e.g., that includes the e-stopper layer 110) described herein in relation to FIGS. 1A-1C may be greater, across a drive current from 0 to 360 mA, than an output power, shown by curve 208, for a similar, but differently structured PIC (e.g., a PIC that has a similar structure as the PIC 102, but does not include the e-stopper layer 110) across the drive current. Put another way, FIG. 2B shows that an amount of drive current that needs to be applied to the PIC 102 to achieve a particular power output may be less for the PIC 102 than for the similar, but differently structured PIC.

As indicated above, FIGS. 2A-2B are provided as an example. Other examples may differ from what is described with regard to FIGS. 2A-2B.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “bottom,” “above,” “upper,” “top,” “left,” “right,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An integrated laser modulator, comprising:
a substrate;
a laser active region disposed on the substrate;
a modulator region disposed on the substrate; and
an e-stopper layer disposed on at least the laser active region, wherein:
the substrate and the laser active region are associated with an indium gallium arsenide phosphide (InGaAsP) material system,
the modulator region is associated with InGaAsP material system or an aluminum indium gallium arsenide (AlInGaAs) material system,
the e-stopper layer comprises aluminum indium arsenide (AlInAs),
the e-stopper layer is disposed greater than 100 nanometers away from a quantum element of the laser active region, and
the modulator region includes an end surface that interfaces with an end surface of the laser active region.

2. The integrated laser modulator of claim 1, wherein:
the e-stopper layer is disposed on the modulator region.

3. The integrated laser modulator of claim 1, wherein:
the substrate is an n-type substrate or a semi-insulating substrate;
the laser active region comprises undoped InGaAsP; and
the e-stopper layer comprises p-doped AlInAs or undoped AlInAS.

4. The integrated laser modulator of claim 3, wherein:
a doped layer that comprises p-doped InP is disposed on at least the e-stopper layer.

5. The integrated laser modulator of claim 1, wherein:
an encapsulating layer comprising p-doped InP or undoped InP is disposed between the laser active region and the e-stopper layer.

6. The integrated laser modulator of claim 1, wherein:
an encapsulating layer comprising p-doped InP or undoped InP is disposed on the e-stopper layer.

7. The integrated laser modulator of claim 1, wherein:
the e-stopper layer includes a top surface and a bottom surface that are not oxidized.

8. The integrated laser modulator of claim 1, wherein the integrated laser modulator is configured to operate at a spectral range from 1250 to 1360 nanometers (nm).

9. The integrated laser modulator of claim 8, wherein the spectral range is centered at 1300 nm.

10. A photonic integrated circuit (PIC), comprising:
a laser active region disposed on a substrate;
a modulator region disposed on the substrate; and
an e-stopper layer disposed on at least the laser active region, wherein:
the laser active region is associated with an indium gallium arsenide phosphide (InGaAsP) material system,
the e-stopper layer comprises aluminum indium arsenide (AlInAs), and
the e-stopper layer is disposed on a separate confinement heterostructure (SCH) layer of the laser active region.

11. The PIC of claim 10, wherein:
the e-stopper layer is disposed on the modulator region.

12. The PIC of claim 10, wherein:
the laser active region comprises undoped InGaAsP; and
the e-stopper layer comprises doped AlInAs.

13. The PIC of claim 12, wherein:
a doped layer that comprises doped InP is disposed on at least the e-stopper layer.

14. The PIC of claim 10, wherein:
an encapsulating layer comprising InP is disposed on the e-stopper layer.

15. An optical device, comprising:
an integrated laser modulator that includes:
a laser active region;
a modulator region; and
an e-stopper layer disposed on at least the laser active region, wherein:
the laser active region is associated with an indium gallium arsenide phosphide (InGaAsP) material system,
the e-stopper layer comprises aluminum indium arsenide (AlInAs), and
the e-stopper layer is disposed greater than 100 nanometers away from a quantum element of the laser active region.

16. The optical device of claim 15, wherein:
the e-stopper layer is disposed on the modulator region.

17. The optical device of claim 15, wherein:
an encapsulating layer comprising InP is disposed between the laser active region and the e-stopper layer.

18. The optical device of claim 15, wherein:
an encapsulating layer comprising InP is disposed on the e-stopper layer.

19. The optical device of claim 15, wherein:
the modulator region includes an end surface that interfaces with an end surface of the laser active region.

20. The optical device of claim 15, wherein the integrated laser modulator is configured to operate at a spectral range from 1250 to 1625 nanometers (nm).
